(19) United States
(12) Patent Application Publication
(10) Pub. No.: US 2025/0149928 A1
(43) Pub. Date: May 8, 2025

(54) WIRELESS CHARGING TRANSMITTER DEVICE

(71) Applicant: STMicroelectronics International N.V., Geneva (CH)

(72) Inventors: Bruno LEDUC, Voiron (FR); Gregoire MONTJAUX, Claix (FR); Christophe GRUNDRICH, Grenoble, Isere (FR); Hubert DEGOIRAT, Villard Bonnot (FR)

(73) Assignee: STMicroelectronics International N.V., Geneva (CH)

(21) Appl. No.: 18/937,718

(22) Filed: Nov. 5, 2024

(30) Foreign Application Priority Data
Nov. 6, 2023 (FR) 2312033

(51) Int. Cl. H02J 50/80; H03K 4/02; H04B 5/43

(52) U.S. Cl. CPC H02J 50/80; H03K 4/02; H04B 5/43

(57) ABSTRACT

A wireless charging transmitter device is includes a square wave signal generation circuit. The square wave signal generation circuit is formed by a first PMOS transistor switching circuit having a group of PMOS performance transistors and at least one PMOS functionality transistor, and a second NMOS transistor switching circuit having a group of NMOS performance transistors and at least one NMOS functionality transistor.

### PRIORITY CLAIM

This application claims the priority benefit of French Application for Patent No. 2312033, filed on Nov. 6, 2023, the content of which is hereby incorporated by reference in its entirety to the maximum extent allowable by law.

### TECHNICAL FIELD

Embodiments relate to wireless charging circuits, particularly wireless charging using Near Field Communication (NFC) technology.

### BACKGROUND

Wireless charging makes it possible to charge electronic devices without using energy received from a physical plugging but rather using energy received from a magnetic field.

Wireless charging using NFC technology has the advantage of being not very demanding in terms of space occupancy and allows antennas to be used on printed circuit boards.

Wireless charging using NFC technology makes it possible to carry out charging of a wireless electronic device over a short distance, for example in the order of 10 cm.

NFC technology is an open technology platform standardized in the standard ISO/IEC 18092 and ISO/IEC 21481 but incorporates many already existing standards such as for example the type A and type B protocols defined in the standard ISO-14443 that may be communication protocols that can be used in NFC technology. Wireless charging using NFC technology is defined by the version 2.0 of the NFC WLC (“Wireless Charging”) specification published in October 2021 by the NFC Forum.

In particular, NFC wireless charging makes it possible to charge relatively small electronic devices, such as wireless headphones and smartwatches, fitness monitoring devices, or other electronic devices of the Internet of Things. For example, electronic devices may be charged by NFC wireless charging from a smartphone or from a dedicated charging station.

More particularly, NFC wireless charging is based on a charging transmitter device (also referred to as “poller”) and on a power receiver device (also referred to as “listener”). The charging transmitter device is used to charge the power receiver device. As indicated above, the charging transmitter device may be a smartphone or a dedicated charging station for example.

The speed of the wireless charging (particularly NFC) depends on the power of the charging signal generated by the charging transmitter device. The more powerful the charging signal generated by the charging transmitter device is, the faster the charging of the power receiver device is accomplished. It is particularly preferable to generate a charging signal having a relatively high power between 1 Watt and 3 Watts.

In order to perform charging of the charge receiver device, the charging signal is generated over a relatively long period during the life of the charging transmitter, particularly greater than 20,000 hours (that is to say 6 hours a day for 10 years). Therefore, the charging signal may be generated over a period of several years during the life of the charging transmitter, whereas the NFC communication is in the order of a few hundreds of hours.

Nevertheless, the fact of generating a charging signal having a high power over a long period may degrade the components of said circuit generating the charging signal of the charging transmitter device. The degradation of these components may degrade the performance of the wireless charging.

The power of the charging signal is defined by the current and the voltage provided to the antenna of the charging transmitter. The current is defined according to the impedance of the antenna and therefore cannot be increased. Furthermore, increasing the current involves increasing the temperature generated by the circuit generating the charging signal. Thus, in order to increase the power of the charging signal, the voltage provided to the antenna of the charging transmitter should rather be increased.

Therefore, components that withstand high voltages should be used for increasing the power of the charging signal. Nevertheless, as seen previously the performance of these components may degrade over time.

In particular, the circuit for generating the charging signal comprises a circuit for generating a differential square wave signal at a given frequency, particularly at 13.56 MHz within the context of NFC charging. The square wave signal reshaped by the electromagnetic interference (EMI) filter then corresponding to the charging signal. The circuit for generating a square wave signal comprises metal-oxide-semiconductor field-effect transistors (MOSFET). These MOSFET devices are controlled in such a way as to generate said square wave signal.

These MOSFET devices are generally designed to obtain a relatively low impedance as output of the charging signal generation circuit. Nevertheless, such transistors are not configured to withstand high drain-source voltages, which may reduce their life.

In order to reduce the loss of performance of a transistor over time, it is possible to increase the length of the channel of this transistor. Nevertheless, this solution involves increasing the size of the charging signal generation circuit.

Therefore, there is a need to propose a solution for providing a charging signal having a relatively high power while reducing the decrease in performance over time of the circuit for generating such a charging signal.

### SUMMARY

According to one aspect, a wireless charging transmitter device is proposed comprising a generation circuit configured to generate a charging signal at a given frequency, an antenna configured to transmit said charging signal, the generation circuit comprising at least one square wave signal generation circuit including: a first PMOS transistor switching circuit comprising a group of PMOS performance transistors and at least one PMOS functionality transistor, said at least one PMOS functionality transistor having an output impedance greater than an output impedance of the PMOS performance transistors; a second NMOS transistor switching circuit comprising a group of NMOS performance transistors and at least one NMOS functionality transistor, said at least one NMOS functionality transistor having an output impedance greater than an output impedance of the NMOS performance transistors.

The PMOS and NMOS functionality transistors are used to ensure the transitions between a high state and a low state of the charging signal. These functionality transistors are configured to withstand relatively high drain-source voltages, for example in the order of 7.5 Volts.

The PMOS and NMOS performance transistors are used to ensure a relatively low output impedance of the generation circuit.

In an advantageous embodiment, the PMOS performance transistors have a source configured to receive a power supply voltage, a drain connected to a drain of the NMOS performance transistors, and a gate configured to receive a first control signal. Furthermore, the NMOS performance transistors also have a source connected to a reference (for example, ground) point and a gate configured to receive a second control signal.

Advantageously, said at least one PMOS functionality transistor has a source configured to receive a power supply voltage, a drain connected to a drain of said at least one NMOS functionality transistor, and a gate configured to receive a third control signal. Furthermore, said at least one NMOS functionality transistor also has a source connected to the reference (ground) point and a gate configured to receive said third control signal.

In an advantageous embodiment, the PMOS performance transistors and the NMOS performance transistors are controlled offset in relation to said at least one PMOS functionality transistor and to said at least one NMOS functionality transistor so as to prevent simultaneously applying a drain-source voltage and a gate-source voltage greater than a voltage threshold defined on the PMOS performance transistors and on the NMOS performance transistors.

The fact of controlling in an offset manner the PMOS and NMOS performance transistors, in relation to said at least one PMOS functionality transistor and to said at least one NMOS functionality transistor, makes it possible to protect the performance transistors from high voltages. It is then possible to increase the drain-source voltage of said at least one PMOS functionality transistor and of said at least one NMOS functionality transistor. In particular, this drain-source voltage may be increased over a long duration without significantly impacting the life of these functionality transistors. The functionality transistors thus have longer lengths in relation to those of the performance transistors. This enables them to be more robust to ageing and thus to maintain good performance over time. Therefore, this makes it possible to increase the life of these functionality transistors. The performance transistors for their part have shorter lengths so as to minimize their occupied surface area. The functionality transistors occupy a smaller surface area in relation to said entire generation circuit. Thus, although the lengths of the functionality transistors are longer than those of the performance transistors, this does not result in a significant increase in the surface area of the generation circuit.

Advantageously, the voltage threshold is between 0.4 Volts and 1 Volt.

Preferably, the wireless charging transmitter device further comprises a control circuit configured to generate the first control signal, the second control signal and the third control signal.

Advantageously, the wireless charging transmitter device further comprises a circuit generating an initial clock signal. Furthermore, the control circuit includes: a first delay circuit configured to receive as input said initial clock signal and to generate as output a first intermediate clock signal temporally offset in relation to the initial clock signal, said first intermediate clock signal corresponding to the third control signal; a second delay circuit configured to receive as input said first intermediate clock signal and to generate as output a second intermediate clock signal temporally offset in relation to the first intermediate clock signal; a first edge selection circuit configured to generate the first control signal from an alternating selection of the initial clock signal and of the second intermediate clock signal; and a second edge selection circuit configured to generate the second control signal from an alternating selection of the initial clock signal and of the second intermediate clock signal, this selection being reversed in relation to the first edge selection circuit.

Preferably, the NMOS performance transistors have an output impedance between 0.5 Ohms and 1 Ohm.

Advantageously, the NMOS performance transistors have a channel length longer than or equal to 0.72 micrometers.

Preferably, the PMOS performance transistors have an output impedance between 0.5 Ohms and 1 Ohm.

Advantageously, the PMOS performance transistors have a channel length longer than or equal to 0.72 micrometers.

Preferably, said at least one NMOS functionality transistor has an output impedance between 5 Ohms and 10 Ohms.

Advantageously, said at least one NMOS functionality transistor has a channel length longer than or equal to 1.44 micrometers, particularly two to three times longer than the channel length of the NMOS performance transistors.

Preferably, said at least one PMOS functionality transistor has an output impedance between 5 Ohms and 10 Ohms.

Advantageously, said at least one PMOS functionality transistor has a channel length longer than or equal to 1.44 micrometers, particularly two to three times longer than the channel length of the PMOS performance transistors.

### BRIEF DESCRIPTION OF THE DRAWINGS

Other advantages and features of the invention will become apparent upon reading the detailed description of embodiments, which are in no way limiting, and of the appended drawings in which:

FIG. 1 illustrates an embodiment of the wireless charging transmitter device;

FIG. 2 illustrates an embodiment of a charging signal generation circuit;

FIG. 3 illustrates an embodiment of a square wave signal generation circuit;

FIG. 4 illustrates an embodiment of a control circuit; and

FIG. 5 shows signal waveforms for clock signals and a square wave signal generated by the square wave signal generation circuit.

### DETAILED DESCRIPTION

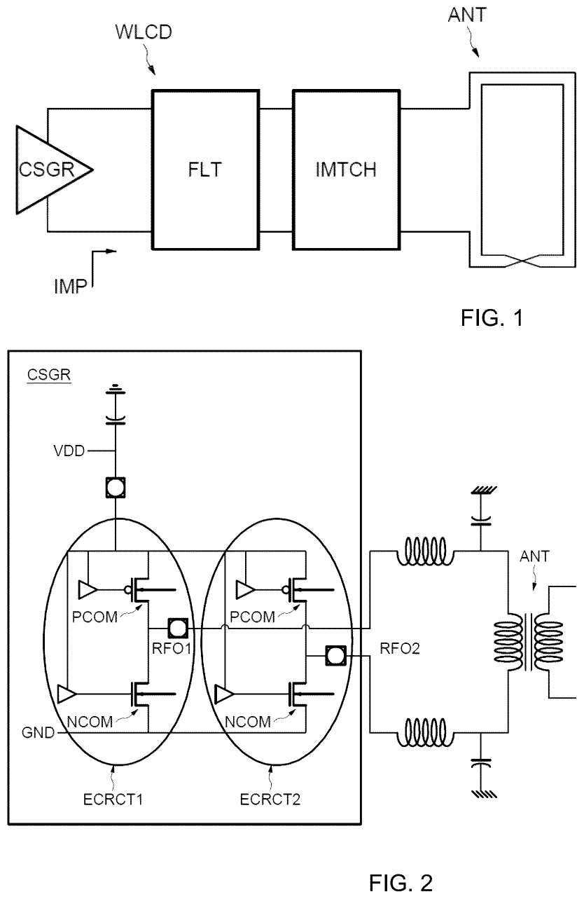

FIG. 1 illustrates an embodiment of a wireless charging transmitter device WLCD.

The charging transmitter device WLCD comprises a power supply source (not shown), a circuit CGSR for generating a charging signal, an electromagnetic interference filter FLT, an impedance matching circuit IMTCH, and an antenna ANT.

The power supply source may be a battery, for example.

The charging signal generation circuit CSGR is configured to generate a charging signal from the power supply source. The charging signal comprises two square wave signals in phase opposition. These square wave signals are transmitted to the antenna ANT via the electromagnetic interference filter FLT and then the impedance matching circuit IMTCH.

The electromagnetic interference filter FLT is a circuit configured to attenuate, or even eliminate, electromagnetic interferences in the square wave signals generated by the charging signal generation circuit CSGR.

The impedance matching circuit IMTCH is configured to match the impedance viewed by the antenna ANT.

The antenna ANT is configured to transmit the charging signal generated by the charging signal generation circuit CSGR.

Such a charging signal can be received by a charging receiver device LST so as to be able to wirelessly charge a battery of the charging receiver device LST.

FIG. 2 illustrates an embodiment of a charging signal generation circuit CSGR as described above. The generation circuit CSGR comprises two square wave signal generation circuits ECRCT1, ECRCT2 operating in phase opposition. The circuits ECRT1 and ECRCT2 are configured to generate respectively the square wave signals RFO1 and RFO2 in phase opposition. These square wave signals RFO1 and RFO2 form the charging signal that is subsequently transmitted by the antenna ANT in a sinusoidal shape after filtering.

Each circuit ECRCT1, ECRCT2 corresponds to a circuit of an inverter chain. Thus, each square wave signal generation circuit ECRCT1, ECRCT2 comprises a PMOS transistor switching circuit PCOM and a NMOS transistor switching circuit NCOM. PMOS transistors are metal-oxide-semiconductor field-effect transistors (MOSFET) of the P type. NMOS transistors are MOSFETs of the N type.

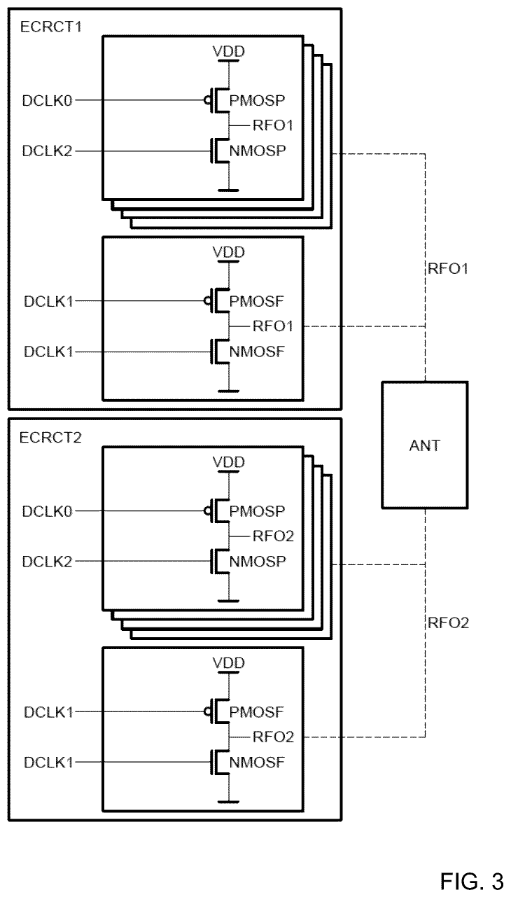

FIG. 3 illustrates an embodiment of the last stage of these circuits ECRCT1 and ECRCT2.

In particular, the PMOS transistor switching circuit PCOM includes a first group of PMOS transistors, referred to as performance transistors PMOSP, and a PMOS transistor, referred to as functionality transistor PMOSF.

In particular, the functionality transistor PMOSF is used to ensure the transition between a low state and a high state of the charging signal. The functionality transistor PMOSF has a relatively high impedance. For example, the functionality transistor PMOSF has an output impedance between 5 Ohms and 10 Ohms, for example in the order of 8 Ohms. In order to obtain such an output impedance, the functionality transistor PMOSF has a channel length longer than or equal to 1.44 micrometers.

The performance transistors PMOSP are configured to improve the performances of the switching circuit. The performance transistors PMOS have a relatively low impedance. For example, the performance transistors PMOSP have an output impedance between 0.5 Ohms and 1 Ohm, for example in the order of 0.5 Ohms. In order to obtain such an output impedance, each performance transistor PMOSP has a channel length longer than or equal to 0.72 micrometers, particularly two to three times shorter than the channel length of the functionality transistors PMOSF.

The NMOS transistor switching circuit includes a first group of NMOS transistors, referred to as performance transistors NMOSP, and at least one other NMOS transistor, referred to as functionality transistor NMOSF.

In particular, a functionality transistor NMOSF is also used to ensure a transition between a low state and a high state of the charging signal. The functionality transistor NMOSF has a relatively high impedance. For example, the functionality transistor NMOSF has an output impedance between 5 Ohms and 10 Ohms, for example in the order of 8 Ohms. In order to obtain such an output impedance, the functionality transistor NMOSF has a channel length longer than or equal to 1.44 micrometers.

The performance transistors NMOSP are configured to improve the performances of the switching circuit. The performance transistors NMOSP have a relatively low impedance. For example, the performance transistors NMOSP have an output impedance between 0.5 Ohms and 1 Ohm, for example in the order of 0.5 Ohms. In order to obtain such an output impedance, each performance transistor NMOSP has a channel length longer than or equal to 0.72 micrometers, particularly two to three times shorter than the channel length of the functionality transistors PMOSF.

The functionality transistor PMOSF and the functionality transistor NMOSF are configured to be switched offset in relation to the performance transistors PMOSP and to the performance transistors NMOSP. In this way, the functionality transistor PMOSF and the functionality transistor NMOSF may be subjected simultaneously to high drain-source voltages and gate-source voltages. Nevertheless, the functionality transistor PMOSF and the functionality transistor NMOSF are configured to withstand such high voltages. Indeed, the functionality transistor PMOSF and the functionality transistor NMOSF have a larger gate size to withstand ageing.

The functionality transistor PMOSF has a source, a drain and a gate. The source of this functionality transistor PMOSF is connected to a power supply source VDD. The gate of this functionality transistor PMOSF is configured to receive a signal DCLK1.

The functionality transistor NMOSF has a source, a drain and a gate. The drain of the functionality transistor NMOSF is connected to the drain of a functionality transistor PMOSF. The drain of each functionality transistor NMOSF is connected to the drain of this functionality transistor PMOSF. The source of this functionality transistor NMOSF is connected to a reference point, particularly to a ground GND. The gate of this functionality transistor NMOSF is configured to receive the signal DCLK1.

The performance transistors PMOSP and the performance transistors NMOSP are configured to be switched offset in relation to the functionality transistor PMOSF and to the functionality transistor NMOSF. In this way, the performance transistors PMOSP and the performance transistors NMOSP are not subjected simultaneously to high drain-source voltages and gate-source voltages. This makes it possible to prevent operating conditions that may result in a hot carrier injection that may degrade the performance transistors PMOSP and the performance transistors NMOSP.

The performance transistor PMOSP has a source, a drain and a gate. The source of this performance transistor PMOSP is connected to the power supply source VDD. The gate of this performance transistor PMOS is configured to receive a signal DCLK0.

The performance transistor NMOSP has a source, a drain and a gate. The drain of each performance transistor NMOSP is connected to the drain of a performance transistor PMOSP. The source of this performance transistor NMOSP is connected to a reference point, particularly to the ground GND. The gate of this performance transistor NMOSP is configured to receive a signal DCLK2.

The charging signal generation circuit also comprises a control circuit COMC. This control circuit COMC is configured to control the transistors PMOSP, PMOSF and NMOSP, NMOSF of the switching circuits PCOM, NCOM.

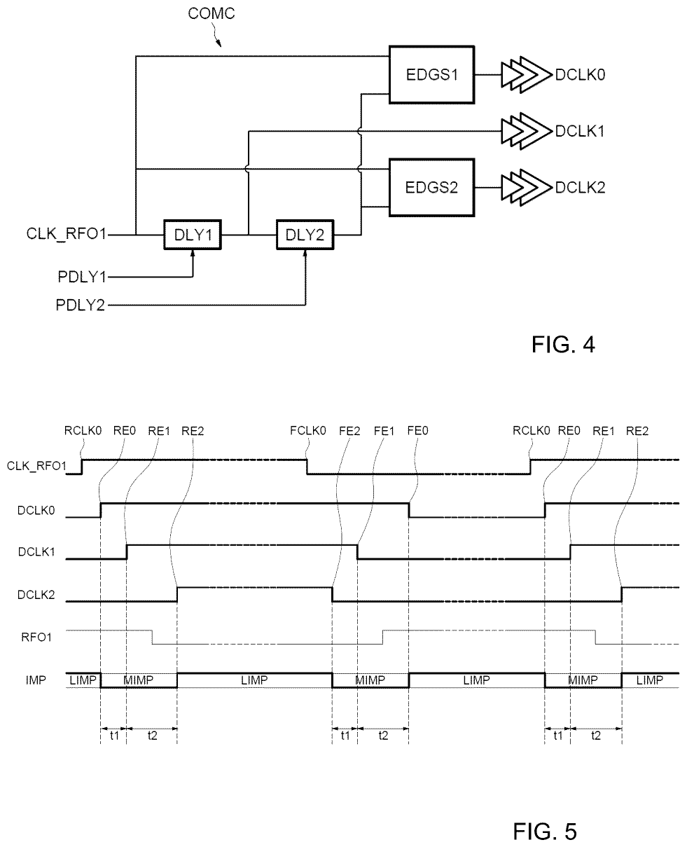

FIG. 4 illustrates an embodiment of such a control circuit COMC. The control circuit COMC is configured to receive a clock signal CLK_RFO1. This clock signal CLK_RFO1 may be provided by a radio frequency oscillator of the wireless charging transmitter device WLCD. The radio frequency oscillator may comprise a phase-locked loop.

The control circuit COMC comprises a first delay circuit DLY1. This first delay circuit DLY1 is configured to receive the clock signal CLK_RFO1 and to generate a signal DCLK1 offset by a duration t1 in relation to the clock signal CLK_RFO1. The duration t1 may be adjusted via a first digital control signal PDLY1. The duration t1 may be between 0.5 nanoseconds and 10 nanoseconds.

The control circuit comprises a second delay circuit DLY2. The second delay circuit DLY2 is configured to receive the signal DCLK1 and to generate a signal TCLK2 offset by a duration t2 in relation to the signal DCLK1, and by the sum of the durations t1 and t2 in relation to the clock signal CLK_RFO1. The duration t2 may be adjusted via a digital control signal PDLY2. The duration t2 may be between 0.5 nanoseconds and 10 nanoseconds.

As described hereinafter, the duration t1 makes it possible to prevent a cross conduction between the performance transistors PMOSP, NMOSP and the functionality transistors PMOSF, NMOSF of each square wave signal generation circuit ECRCT. The duration t2 makes it possible to improve the life of the performance transistors PMOSP, NMOSP and the functionality transistors PMOSF, NMOSF of each square wave signal generation circuit by preventing a relatively high drain-source voltage and gate-source voltage from being provided simultaneously.

The control circuit also comprises a first edge selection circuit EDGS1. The first edge selection circuit is configured to receive the clock signal CLK_RFO1 and the signal TCLK2. The first edge selection circuit EDGS1 is configured to deliver as output a signal DCLK0 corresponding either to the clock signal CLK_RFO1 or to the signal TCLK2. In particular, the first edge selection circuit EDGS1 includes a set of logic gates for generating the signal DCLK0.

The control circuit also comprises a second edge selection circuit EDGS2. The second edge selection circuit EDGS2 is configured to receive the clock signal CLK_RFO1 and the signal TCLK2. The second edge selection circuit EDGS2 is configured to deliver as output a signal DCLK2 corresponding either to the clock signal CLK_RFO1 or to the signal TCLK2. In particular, the second edge selection circuit EDGS2 includes a set of logic gates for generating the signal DCLK2.

The control circuit comprises a first buffer circuit BUF0. The first buffer circuit is configured to receive the unbuffered signal DCLK0 and to deliver this buffered signal DCLK0 on the gate of the performance transistors PMOS.

The control circuit comprises a second buffer circuit BUF1. The second buffer circuit is configured to receive the unbuffered signal DCLK1 and to deliver this buffered signal DCLK1 on the gate of the functionality transistor PMOSF and on the gate of the functionality transistor NMOSF.

The control circuit comprises a third buffer circuit BUF2. The third buffer circuit is configured to receive the unbuffered signal DCLK2 and to deliver this buffered signal DCLK2 on the gate of the performance transistors NMOSP.

The control circuit therefore generates three control signals DCLK0, DCLK1 and DCLK2. The signal DCLK0 is used to control the performance transistors PMOSP. The signal DCLK1 is used to control the functionality transistor PMOSF and to control the functionality transistor NMOSF. The signal DCLK2 is used to control the performance transistors NMOSP.

FIG. 5 shows the signals DCLK0, DCLK1 and DCLK2 as well as a square wave signal generated by a square wave signal generation circuit during a clock cycle.

As illustrated in this FIG. 5, on each clock cycle CLK_RFO1, the control circuit is configured to generate a signal DCLK0 having:
a delayed falling edge FE0 of said duration t2 in relation to a falling edge FE1 of the signal DCLK1 and delayed by the sum of the durations t1 and t2 in relation to a falling edge FE2 of the signal DCLK2 (the signal DCLK0 then being generated by selecting the falling edge of the signal TCLK2, and the signal DCLK2 then being generated by selecting the falling edge FCLK0 of the signal CLK_RFO1), and
an advanced rising edge RE0 of said duration t1 in relation to a rising edge RE1 of the signal DLCK1 and advanced by the sum of the durations t1 and t2 in relation to a rising edge RE2 of the signal DCLK2 (the signal DCLK0 then being generated by selecting the rising edge RCLK0 of the signal CLK_RFO1, and the signal DCLK2 then being generated by selecting the rising edge of the signal TCLK2).

Thus, before the falling edge FE2 of the signal DCLK2, the output impedance IMP of the square wave signal generation circuit corresponds to the output impedance of the performance transistors and is therefore a relatively low impedance LIMP. Between the falling edge FE2 of the signal DCLK2 and the falling edge FE0 of the signal DCLK0, the output impedance IMP of the square wave signal generation circuit corresponds to a medium impedance MIMP between the output impedance of the functionality transistors and the output impedance of the performance transistors. Between the falling edge FE0 of the signal DCLK0, the rising edge RE0 of the signal DCLK0, the output impedance IMP of the square wave signal generation circuit corresponds to the output impedance of the performance transistors and is therefore a relatively low impedance LIMP. Between the rising edge RE0 of the signal DCLK0 and the rising edge RE2 of the signal DCLK2, the output impedance IMP of the square wave signal generation circuit corresponds to a medium impedance MIMP between the output impedance of the functionality transistors and the output impedance of the performance transistors. After the rising edge RE2 of the signal DCLK2, the output impedance IMP of the square wave signal generation circuit corresponds to the output impedance of the performance transistors and is therefore a relatively low impedance LIMP.

In this way, the functionality transistor PMOSF and the functionality transistor NMOSF are configured to simultaneously receive a relatively high drain-source voltage and gate-source voltage. Thus, the functionality transistor PMOSF and the functionality transistor NMOSF may operate under conditions that may result in a hot carrier injection. Nevertheless, the functionality transistor PMOSF and the functionality transistor NMOSF are configured to withstand these operating conditions. Indeed, these functionality transistors NMOSF, PMOSF have a gate size that is large enough to withstand these operating conditions.

The performance transistors PMOSP and the performance transistors NMOSP are configured to prevent simultaneously receiving a relatively high drain-source voltage and gate-source voltage. Thus, the performance transistors PMOSP and the performance transistors NMOSP are prevented from operating under conditions that may result in a hot carrier injection. Therefore, it is possible to use performance transistors having a relatively high output impedance. This makes it possible to use performance transistors NMOSP, PMOSP of reduced lengths in relation to the functionality transistors NMOSF, PMOSF.

In this way, it is possible to increase the voltage of the charging signal generated by the circuit CSGR. Thus, it is possible to transmit a charging signal having a relatively high power, for example between 1 Watt and 3 Watts. Such a power may therefore be obtained with a charging signal generation circuit having transistors that have on average relatively short channel lengths. Indeed, in such a generation circuit, only the functionality transistors NMOSF, PMOSF have a channel length long enough to simultaneously withstand a relatively high gate-source voltage and drain-source voltage, the performance transistors NMOSP, PMOSP having a shorter channel length.

1. A wireless charging transmitter device, comprising:
a signal generation circuit configured to generate a charging signal at a given frequency; and
an antenna configured to transmit said charging signal;
wherein the signal generation circuit comprises at least one square wave signal generation circuit including:
a first PMOS transistor switching circuit comprising a group of PMOS performance transistors and at least one PMOS functionality transistor, said at least one PMOS functionality transistor having an output impedance greater than an output impedance of the PMOS performance transistors; and
a second NMOS transistor switching circuit comprising a group of NMOS performance transistors and at least one NMOS functionality transistor, said at least one NMOS functionality transistor having an output impedance greater than an output impedance of the NMOS performance transistors.

2. The device according to claim 1:
wherein the PMOS performance transistors have a source configured to receive a power supply voltage, a drain, and a gate configured to receive a first control signal; and
wherein the NMOS performance transistors have a source connected to a reference point, a drain connected to the drain of the PMOS performance transistors, and a gate configured to receive a second control signal.

3. The device according to claim 2:
wherein said at least one PMOS functionality transistor has a source configured to receive the power supply voltage, a drain, and a gate configured to receive a third control signal; and
wherein said at least one NMOS functionality transistor has a source connected to the reference point, a drain connected to the drain of the at least one PMOS functionality transistor, and a gate configured to receive said third control signal.

4. The device according to claim 3, further comprising a control circuit configured to:
control the PMOS performance transistors and the NMOS performance transistors offset in relation to said at least one PMOS functionality transistor and said at least one NMOS functionality transistor so as to prevent simultaneous application of a drain-source voltage and a gate-source voltage greater than at least one voltage threshold defined on the PMOS performance transistors and on the NMOS performance transistors.

5. The device according to claim 4 wherein the voltage threshold is between 0.4 Volts and 1 Volt.

6. The device according to claim 3, further comprising a control circuit configured to generate the first control signal, the second control signal and the third control signal.

7. The device according to claim 6, wherein the control circuit includes:
a first delay circuit configured to receive an initial clock signal and to generate a first intermediate clock signal temporally offset in relation to the initial clock signal, said first intermediate clock signal corresponding to the third control signal;
a second delay circuit configured to receive said first intermediate clock signal and to generate a second intermediate clock signal temporally offset in relation to the first intermediate clock signal;
a first edge selection circuit configured to generate the first control signal from an alternating selection of the initial clock signal and the second intermediate clock signal; and
a second edge selection circuit configured to generate the second control signal from an alternating selection of the initial clock signal and the second intermediate clock signal;
wherein the alternating selection for the second edge selection circuit is reversed in relation to the alternating selection for the first edge selection circuit.

8. The device according to claim 1, wherein the NMOS performance transistors have an output impedance between 0.5 Ohms and 1 Ohm.

9. The device according to claim 8, wherein the NMOS performance transistors have a channel length longer than or equal to 0.72 micrometers.

10. The device according to claim 1, wherein the PMOS performance transistors have an output impedance between 0.5 Ohms and 1 Ohm.

11. The device according to claim 10, wherein the PMOS performance transistors have a channel length longer than or equal to 0.72 micrometers.

12. The device according to claim 1, wherein said at least one NMOS functionality transistor has an output impedance between 5 Ohms and 10 Ohms.

13. The device according to claim 12, wherein said at least one NMOS functionality transistor has a channel length longer than or equal to 1.44 micrometers.

14. The device according to claim 1, wherein said at least one PMOS functionality transistor has an output impedance between 5 Ohms and 10 Ohms.

15. The device according to claim 14, wherein said at least one PMOS functionality transistor has a channel length longer than or equal to 1.44 micrometers.

16. A device, comprising:
an output node configured to output a charging signal for application to a first terminal of an antenna;
a first inverter circuit including a PMOS performance transistor switch coupled in series with an NMOS performance transistor switch at the output node, wherein a gate of the PMOS performance transistor switch is driven by a first clock signal and a gate the NMOS performance transistor switch is driven by a third clock signal;
a second inverter circuit including a PMOS functional transistor switch coupled in series with an NMOS functional transistor switch at the output node, wherein a gate of the PMOS functional transistor switch and a gate the NMOS functional transistor switch are driven by a second clock signal; and
a control circuit configured to generate the first, second and third clock signals from a reference clock signal where:
a leading edge of the second clock signal is delayed from a leading edge of the first clock signal and a leading edge of the third clock signal is delayed from a leading edge of the second clock signal; and
a trailing edge of the first clock signal is delayed from a trailing edge of the second clock signal and a trailing edge of the second clock signal is delayed from a trailing edge of the third clock signal.

17. The device of claim 16, wherein:
the PMOS functional transistor switch has an output impedance greater than an output impedance of the PMOS performance transistor switch; and
the NMOS functional transistor switch has an output impedance greater than an output impedance of the NMOS performance transistor switch.

18. The device according to claim 16:
wherein sources of the PMOS and NMOS performance transistor switches are coupled power supply voltage and reference voltage nodes, respectively; and
wherein sources of the PMOS and NMOS functional transistor switches are coupled power supply voltage and reference voltage nodes, respectively.

19. The device of claim 16, wherein the leading and trailing edge delays for the first, second and third clock signals are configured to prevent simultaneous application of a drain-source voltage and a gate-source voltage greater than at least one voltage threshold defined on the PMOS performance transistor switch and on the NMOS performance transistor switch.

20. The device of claim 16, wherein the control circuit comprises:
a first delay circuit configured to receive the reference clock signal and to generate a first intermediate clock signal temporally offset in relation to the initial clock signal, wherein said third control signal is derived from said first intermediate clock signal;
a second delay circuit configured to receive said first intermediate clock signal and to generate a second intermediate clock signal temporally offset in relation to the first intermediate clock signal;
a first edge selection circuit configured to generate the first control signal from an alternating selection of the reference clock signal and the second intermediate clock signal; and
a second edge selection circuit configured to generate the second control signal from an alternating selection of the reference clock signal and the second intermediate clock signal;
wherein the alternating selection for the second edge selection circuit is reversed in relation to the alternating selection for the first edge selection circuit.
